(19) United States
(12) Patent Application Publication
(10) Pub. No.: US 2002/0158647 A1
(43) Pub. Date: Oct. 31, 2002

(54) Apparatus for manufacturing semiconductor device, method for manufacturing semiconductor device, inspection apparatus for semiconductor device, and inspection method for semiconductor device

(76) Inventor: Masaaki Sugimoto, Tokyo (JP)

Correspondence Address: McGinn & Gibb, PLLC, 8321 Old Courthouse Road, Suite 200, Vienna, VA, 22182-3817, US

(21) Appl. No.: 09/828,848

(22) Filed: Apr. 10, 2001

(30) Foreign Application Priority Data
Apr. 11, 2000 (JP) 2000-109585

(51) Int. Cl. G01R 31/26

(52) U.S. Cl. 324/765

(57) ABSTRACT

An incomplete circuit pattern is formed. The incomplete circuit pattern includes a circuit targeted for inspection in said product semiconductor device and the other circuit of said product semiconductor device which is not targeted for inspection and in which at least an arbitrary portion of the other circuit is missing. The product semiconductor device will become a product. Then, arbitrary circuit pattern is coupled with the missing portion to form an inspection semiconductor device. The inspection semiconductor device is used to inspect the product semiconductor device.

### BACKGROUND OF THE INVENTION

1. Field of the Invention

The present invention relates to an apparatus and method for manufacturing a semiconductor device such as an LSI (large scaled integrated circuit) and an inspection and analysis apparatus and method for a semiconductor device. In particular, the present invention relates to an apparatus and method for manufacturing a semiconductor device and an inspection and analysis apparatus and method for a semiconductor device capable of inspecting and analyzing electrical characteristics of the semiconductor device with ease and low cost.

2. Description of the Related Art

A plurality of external electrodes are provided to be connected to an external electric circuit in a general semiconductor device. On the other hand, only external electrodes are not sufficient in order to thoroughly investigate electrical characteristics of an internal circuit in an semiconductor device represented by a large scaled and complicated system LSI (large scale integrated circuit), there is provided, for example, means for providing an internal electrode in the device as well as external electrodes. However, an increased number of external electrodes increases the size of the device, which is disadvantageous on an aspect of manufacturing cost. As another means, there is a technique of incorporating a self-diagnosis unit in a semiconductor device. However, in this technique, a design work of a self-diagnosis unit concerning its device circuit itself becomes a large burden on a device designer. Thus, in the case of a short development period and in the case of a low device sales price, it has been difficult to incorporate a self-diagnosis unit with its high performance.

In addition, it is helpful that a simple self-diagnosis circuit is incorporated in a product circuit; two types of semiconductor devices, i.e., a semiconductor device for the purpose of manufacture (hereinafter, referred to as a “product”) and a semiconductor device for monitoring a manufacture history of the semiconductor device (hereinafter, referred to as TEG (Test Elementary Group)) are manufactured on a same semiconductor substrate; and the electronic characteristics of these devices are inspected and analyzed, thereby investigating a product quality.

For example, in a method of manufacturing a semiconductor device, a plurality of wiring layers and insulation layers are alternately laminated each other. Layers of shape patterns that differ depending on each layer are formed, thereby making it possible to check disturbance in film thickness and pattern shape of each layer. A semiconductor device on which these pattern layers are formed is one kind of TEG. In addition, elements similar to a transistor, a diode, a resistor, a capacitor or the like configuring a product circuit are formed singly, in series, or in parallel, whereby the electrical characteristics of a simplex may be measured. These elements are one kind of TEG. Occasionally, a simple logical circuit is formed by combining some kinds of elements with each other, whereby the performance of a product circuit including similar logical circuit may be investigated. These circuits are one kind of TEG also.

On the other hand, there is proposed a reductive projection type exposure apparatus for the purpose of freely forming many kinds of LSIs on a region in which the same wafers are specified (Japanese Patent Application Laid-open No. Sho 61-36930). In a method of manufacturing an LSI using this conventional reductive projection type exposure apparatus, an original drawing pattern for plural types of LSIs is formed in advance in one reticule. In forming a target LSI, an original drawing pattern other than the target LSI is shielded, thereby continuously exposing only the target LSI.

In addition, there is proposed a method of manufacturing a semiconductor apparatus for the purpose of reducing the number of replacement works on an original board (Japanese Patent Application Laid-open No. Sho 62-5644). In this conventional method of manufacturing a semiconductor apparatus, a plurality of original board patterns are provided on one original board, a pattern other than target original board pattern is repeatedly shielded and exposed employing a blade.

However, TEG inspection and analysis is indirect inspection and analysis that are not carried out for a product itself. Thus, in the case where a correlation between the cause of a product failure and the case of a TEG failure is weak, the step that causes such a failure cannot be well identified, and the cause of a failure is likely to be missed. In particular, in the case where different designers or design companies partially design a plurality of product circuits, and a final product is designed by coupling partial circuits (hereinafter, referred to as IP) with each other, it is difficult to design and develop a TEG covering individual IP electrical characteristics.

Conversely, a TEG having its strong correlation with the cause of product failures is not used for inspection and analysis of another product because of its strong dependency on such a product. In addition, in attempting to cover the cause of a product failure, the TEG becomes large scaled and complicated. Thus, the TEG design period is extended, which is disadvantageous in cost efficiency. Moreover, there is a problem that, every time the cause of a new failure is found, TEG redesign and additional design are newly required for detecting such a cause.

In addition, in a conventional exposure apparatus proposed in Japanese Patent Application Laid-open No. Sho 61-36930 and a conventional manufacturing method proposed in Japanese Patent Application No. Sho 62-5644, a pattern can be shielded only in rectangular LSI units that is a simple shape. Thus, an arbitrary portion of a complicated product circuit pattern inside the LSI cannot be shielded in an arbitrary shape, and an arbitrary circuit pattern cannot be additionally formed after the shielding. Therefore, there is a problem that the internal circuit of an LSI cannot be analyzed in detail.

### SUMMARY OF THE INVENTION

It is an object of the present invention to provide a method and apparatus for manufacturing a semiconductor device and an inspection apparatus and method for a semiconductor device capable of identifying the cause of an electrical failure of a semiconductor device that will become a product in a short period of time; capable of efficiently carrying out inspection as compared with a conventional TEG; and capable of reducing the cost.

According to one aspect of the present invention, an apparatus for manufacturing a semiconductor device with an inspection semiconductor device which is used to inspect the product semiconductor device comprises: a pattern forming unit which forms an incomplete circuit pattern, the incomplete circuit pattern including a circuit targeted for inspection in the product semiconductor device and the other circuit of the product semiconductor device which is not targeted for inspection and in which at least an arbitrary portion of the other circuit is missing; and a device forming unit which couples arbitrary circuit pattern with the missing portion to form the inspection semiconductor device.

In the present invention, a region for a circuit targeted for inspection of a product semiconductor device is provided in an incomplete circuit pattern, and apparatus coupling another arbitrary circuit pattern is provided at the missing portion of the incomplete circuit pattern. Thus, if such another arbitrary circuit pattern is defined as a circuit pattern capable of inspection of the incomplete circuit pattern, a circuit targeted for inspection can be inspected, thus making it possible to inspect the product semiconductor device itself. Therefore, it is possible to achieve high precision with respect to identification of electrical failures as compared with a conventional TEG. In addition, as the pattern forming apparatus, there may be provided a shield member or the like for shielding a mask for forming the product semiconductor device, for example and a part of this mask. Thus, design can be made easily and within a short period of time.

If the product semiconductor device and the inspection semiconductor device are formed in a same semiconductor wafer, the deviation in electrical characteristics based on material properties can be reduced between the product semiconductor device and the inspection semiconductor device.

According to another aspect of the present invention, a method for manufacturing a semiconductor device with an inspection semiconductor device which is used to inspect the product semiconductor device comprises the steps of: forming an incomplete circuit pattern, the incomplete circuit pattern including a circuit targeted for inspection in the product semiconductor device and the other circuit of the product semiconductor device which is not targeted for inspection and in which at least an arbitrary portion of the other circuit is missing; and coupling arbitrary circuit pattern with the missing portion to form the inspection semiconductor device.

According to another aspect of the present invention, an inspection apparatus for an inspection semiconductor device manufactured by the above-described manufacturing apparatus comprises a comparator which compares electrical characteristics of the product semiconductor device with those of a circuit in a region corresponding to the incomplete circuit pattern.

According to another aspect of the present invention, an inspection method for an inspection semiconductor device manufactured by the above-described manufacturing apparatus comprises the step of comparing electrical characteristics of the product semiconductor device with those of a circuit in a region corresponding to the incomplete circuit pattern.

If the electrical characteristics of the product semiconductor device are compared with those of the circuit corresponding to the incomplete circuit pattern and the comparison result is not satisfactory, the incomplete circuit pattern is corrected until the satisfactory result has been obtained. When the comparison result is satisfactory, inspection and analysis are repeated while correcting a missing portion of the incomplete circuit pattern, whereby the product semiconductor device can be inspected and analyzed.

According to the present invention, there is provided device forming apparatus coupling arbitrary circuit pattern with a missing portion of an incomplete circuit pattern. Thus, such another arbitrary circuit pattern is defined as a circuit pattern capable of inspection of an incomplete circuit pattern, whereby a circuit targeted for inspection can be inspected, and the product semiconductor device itself can be inspected. Therefore, higher precision can be achieved with respect to identification of the cause of an electrical failure as compared with a conventional TEG technique.

In addition, there may be additionally designed only a combination of a wiring mask and an interlayer insulation layer mask in order to be capable of direct inspecting a mask shielding a portion other than a circuit targeted for inspection and electrical characteristics of a circuit targeted for inspection to the product semiconductor device. Thus, a designing work can be shared with a circuit designer who does not have knowledge concerning a conventional self-diagnosis unit, and a burden on a product circuit designer can be reduced. In addition, even in the case where detailed analysis is carried out in combination with a required external circuit, the external circuit itself can be used as a library independent of a product, and thus, a burden on the product designer can be reduced.

Further, a pattern design of a product semiconductor device can be made independent of a pattern design of wiring for inspecting and analyzing a circuit targeted for inspection after a circuit layout has been determined. Thus, a design period can be reduced as compared with a conventional manufacturing method in which a product and a self-diagnosis unit are designed as one device.

Furthermore, in the case where there exist a plurality of candidates of circuits targeted for inspection, for example, in the case of the same functions and different design companies or in the case where there is a slight structural difference, even in the case where states before and after design change are compared with each other, these characteristics can be easily compared directly with each other. Thus, an optimal circuit configuration can be determined within a short period of time.

Yet furthermore, an inspection and analysis circuit with its high product dependency can be easily designed. Thus, a design period can be reduced, and a low inspection and analysis cost can be achieved as compared with a case of designing a TEG with its high performance and complexity.

### BRIEF DESCRIPTION OF THE DRAWINGS

FIG. 1 is a block diagram depicting an apparatus for manufacturing a semiconductor device according to a first embodiment of the present invention;

FIG. 2 is a flow chart showing a method for manufacturing a semiconductor device using the manufacturing apparatus according to the first embodiment;

FIG. 3A to FIG. 3C are sectional views each sequentially showing the steps of forming a circuit targeted for inspection and analysis, included in the manufacturing method using the apparatus for manufacturing the semiconductor device according to the first embodiment;

FIG. 4A and FIG. 4B are plan views each sequentially showing the steps of forming an inspection and analysis wiring included in the manufacturing method using the apparatus for manufacturing the semiconductor device according to the first embodiment;

FIG. 5A to FIG. 5C are sectional views each sequentially showing the steps that are the same as those shown in FIGS. 4A and 4B;

FIG. 6 is a flow chart showing a method for inspecting the semiconductor device manufactured according to the first embodiment;

FIG. 7A to FIG. 7D are sectional views each sequentially showing the steps of forming a circuit targeted for inspection and analysis, included in a manufacturing method using an apparatus for manufacturing a semiconductor device according to a second embodiment of the present invention;

FIG. 8A to FIG. 8D are sectional views each sequentially showing the steps of forming a circuit targeted for inspection and analysis, included in a method for manufacturing a semiconductor device according to a third embodiment of the present invention;

FIG. 9A to FIG. 9C are sectional views each sequentially showing the steps of forming a circuit targeted for inspection and analysis, included in a method for manufacturing a semiconductor device according to a fourth embodiment of the present invention;

FIG. 10 is a block diagram depicting an apparatus for manufacturing a semiconductor device according to a fifth embodiment of the present invention;

FIG. 11 is a flow chart showing a method for manufacturing a semiconductor device using the manufacturing apparatus according to the fifth embodiment;

FIG. 12A to FIG. 12C are plan views each sequentially showing the steps of forming an inspection and analysis wiring and an inspection and analysis circuit, included in the manufacturing method using the apparatus for manufacturing the semiconductor device according to the fifth embodiment of the present invention;

FIG. 13A to FIG. 13D are plan views each sequentially showing the steps that are identical to those shown in FIGS. 12A to 12D;

FIG. 14 is a flow chart showing a method for inspecting the semiconductor device manufactured according to the fifth embodiment of the present invention;

FIG. 15 is a plan view showing an example of a layout in a wafer when any of the first to fifth embodiments is used;

FIG. 16 is a plan view showing a first example of a layout in a sixth embodiment;

FIG. 17 is a plan view showing a second example of a layout in the sixth embodiment;

FIG. 18 is a plan view showing a third example of a layout in the sixth embodiment;

FIG. 19A and FIG. 19B are plan views each sequentially showing the steps of forming an inspection and analysis wiring and an inspection and analysis circuit, included in a manufacturing method using an apparatus for manufacturing a semiconductor device according to the sixth embodiment of the present invention; and

FIG. 20A to FIG. 20C are plan views each sequentially showing the steps identical to those shown in FIGS. 19A and 19B.

### DESCRIPTION OF THE PREFERRED EMBODIMENT

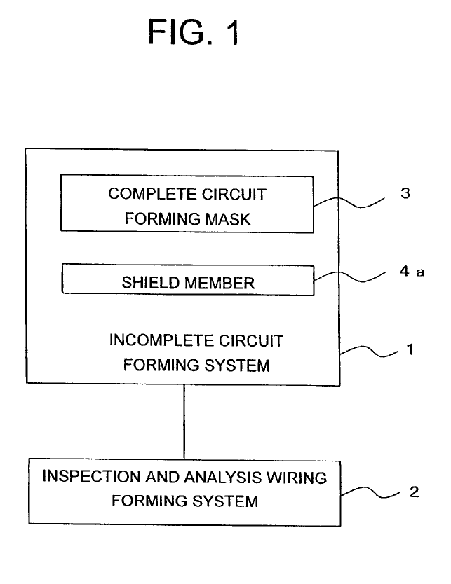

Hereinafter, preferred embodiments of the present invention will be specifically described with reference to the accompanying drawings. FIG. 1 is a block diagram showing an apparatus for manufacturing a semiconductor device according to a first embodiment of the present invention.

There is provided with an incomplete circuit forming system 1 for forming a circuit targeted for inspection and analysis without forming all or part thereof with respect to the portion other than the circuit targeted for inspection and analysis, which is targeted for inspection, of the circuits in a designed product to the manufacturing apparatus according to the present embodiment. In addition, there is provided with an inspection and analysis wiring forming system 2 for forming an inspection and analysis wiring used for electrical inspection and analysis of the circuit targeted for inspection and analysis. The inspection and analysis wiring has a configuration that differs from a portion at which the circuit targeted for inspection and analysis has been removed from the circuits in the designed product.

There is provided with a device (not shown) such as a film forming device, an exposure device, an etching device a scattering device and the like used for manufacturing a semiconductor device represented by a general LSI to the incomplete circuit forming system 1. Among them, as the exposure device, there can be used a stepper device or a scanner device whose light source is an ultra-violet ray or an X-ray, which is an electromagnetic wave with its shorter wavelength than a visible light. In addition, a circuit pattern can be directly imaged by using an electron beam.

In addition, the incomplete circuit forming system 1 includes one or more complete circuit forming mask 3 having formed thereon a pattern for forming all circuits in a designed product and a shield member 4a for shielding a portion not formed at a portion other than a circuit targeted for inspection and analysis.

Alternatively, an inspection and analysis wiring forming system 2 has one or more masks (not shown) required for manufacturing a wiring required for inspection and analysis of the circuit targeted for inspection and analysis.

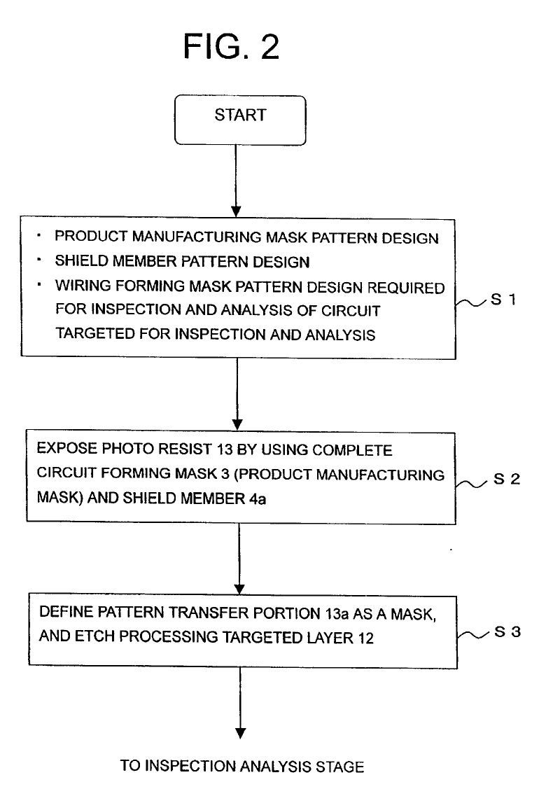

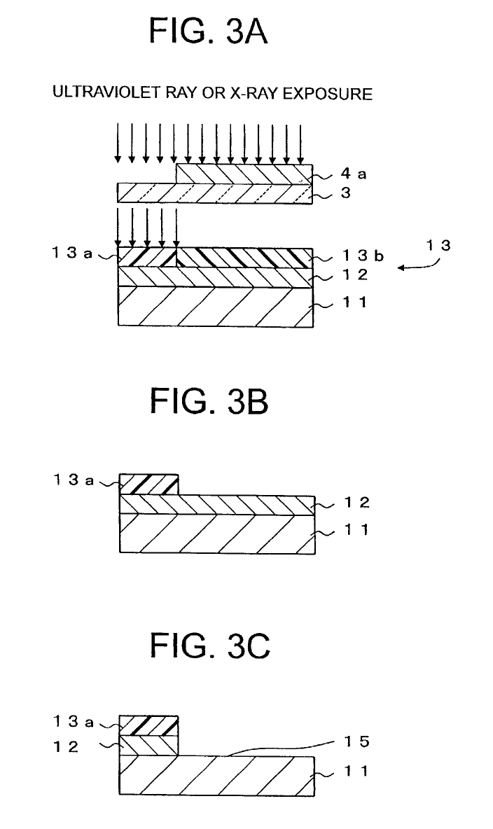

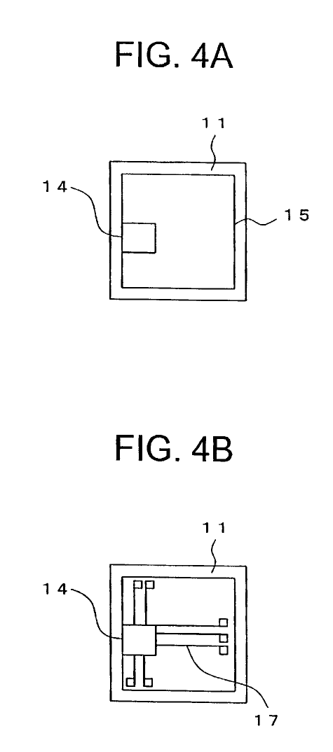

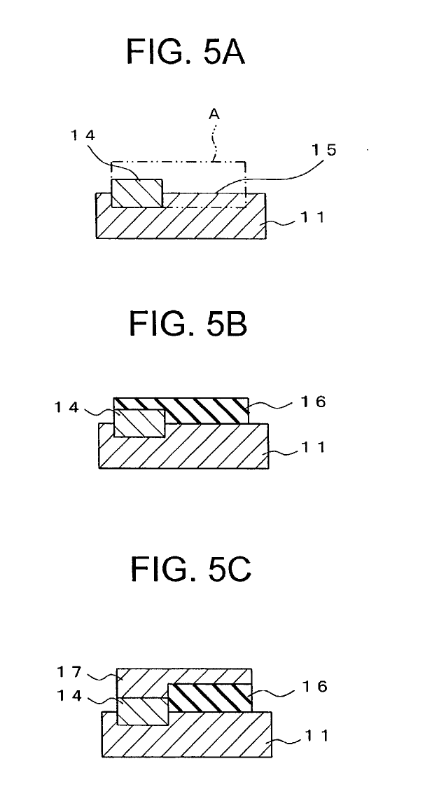

Now, a method for manufacturing a semiconductor application apparatus by using the above configured manufacturing apparatus according to the first embodiment will be described here. FIG. 2 is a flow chart showing a method for manufacturing a semiconductor device. FIG. 3A to FIG. 3C are sectional views each sequentially showing the steps of forming a circuit for inspection and analysis, included in a manufacturing method using the apparatus for manufacturing the semiconductor device according to the first embodiment of the present invention. FIG. 4A and FIG. 4B are plan views each sequentially showing the steps of forming an inspection and analysis wiring included in the manufacturing method using the apparatus for manufacturing the semiconductor device according to the first embodiment of the present invention. FIG. 5A to FIG. 5C are sectional views each sequentially showing the same steps.

First, at a design stage, one or more mask patterns required for manufacturing a product is designed. Some of the circuits included in these patterns are then designed as a pattern of a shield member for shielding all or partial region of a circuit that is not required for inspection and analysis of a circuit targeted for inspection and analysis. Further, there is designed one or more mask patterns required for manufacturing a wiring required for inspection and analysis of a circuit targeted for inspection and analysis (step S1).

Next, at an actual processing stage, as shown in FIG. 3A, a processing targeted layer 12 is formed on a substrate 11. The processing targeted layer 12 is a metal layer for forming a wiring or an insulation film for insulating separation or the like, for example. Then, a photo resist 13 is formed on the processing targeted layer 12. The photo resist 13 may be characterized such that a portion free of being photo-sensed is removed by developing and washing after exposure. Then, a shield member 4a is brought into intimate contact with a light source side in a predetermined region of a complete circuit forming mask 3, the contacted material is defined as a mask, and a photo resist 13 is exposed by an ultraviolet-ray or an X-ray (step S2). As a result, a circuit pattern that is not light-shielded by the shield member 4a of the complete circuit forming mask 3 is transferred to only a region in which the photo resist 13 is photo-sensed. Namely, at this time, a pattern transfer portion 13a and a non-photosensitive portion 13b exist at the photo resist 13.

Next, as shown in FIG. 3B, the non-photo sensitive portion 13b in the photo resist 13 is removed by developing and washing.

As shown in FIG. 3C, the pattern transfer portion 13a in the photo resist 13 is defined as a mask, and a processing targeted layer 12 is etched (step S3). As a result, the processing targeted layer 12 is patterned in the shape of a circuit pattern that is not light-shielded by the shield member 4a of the complete circuit forming mask 3.

Then, by repeating these steps, an inspection and analysis targeted circuit 14 is completed on a predetermined region of the substrate 11, as shown in FIG. 4A and FIG. 5A. At this time, on the substrate 11 light-shielded by the shield member 4a, there exists a region 15 in which a circuit pattern does not exist. In FIG. 5A, a region “A” enclosed within a two-dot chain line indicates a region in which an essentially designed circuit is formed.

Next, as shown in FIG. 5B, an interlayer insulation layer 16 is formed on the entire surface including the region 15 in which a circuit pattern does not exist. As a result, the region 15 is completely covered with the interlayer insulation film 16.

Further, on the interlayer insulation film 16, the other insulation film and a wiring layer (not shown) or the like are formed in a proper number of layers, an electrode is properly formed in the insulation layer conveniently, a wiring layer is further formed on the insulation layer, and the electrode and wiring layer are connected to each other, thereby forming an inspection and analysis wiring 17 used for inspection and analysis of an operation of the inspection and analysis targeted circuit 14, as shown in FIG. 4B and FIG. 5C.

In parallel to such a manufacturing steps, a product semiconductor device designed by using a complete circuit forming mask 3 without using the shield member 4a or the like is manufactured at the same time.

In addition, some of the circuits in the designed product should be formed in a region light-shielded by the shield member 4a, and are indispensable for an operation of the inspection and analysis targeted circuit 14. Therefore, in such a case, such indispensable circuits and wirings are included in the inspection and analysis wiring 17, and substantial connection of a circuit required for inspection and analysis may be made.

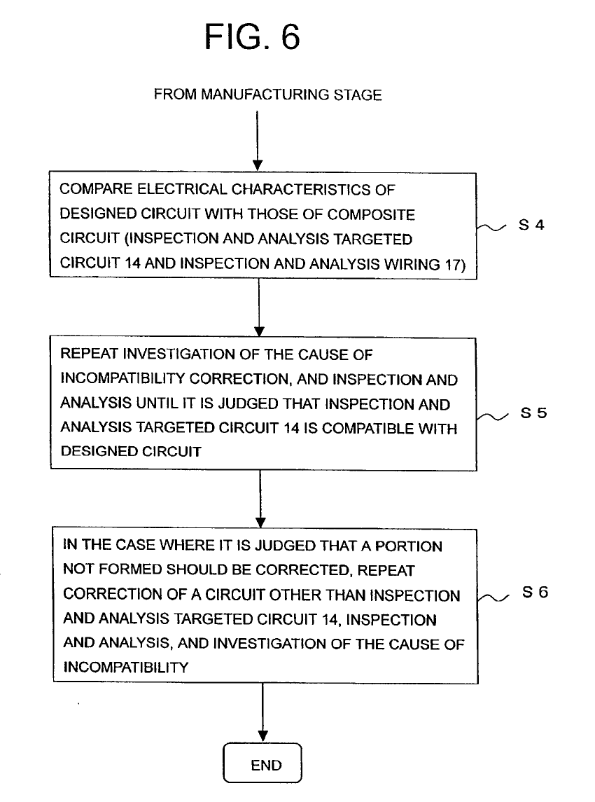

Then, electrical characteristics of the thus manufactured product semiconductor and inspection semiconductor device are inspected and analyzed. FIG. 6 is a flow chart showing a method for inspecting a semiconductor device manufactured according to the first embodiment.

At an inspection and analysis stage, electrical characteristics of a designed circuit formed on the same substrate 11 and a composite circuit of the inspection and analysis targeted circuit 14 and the inspection and analysis wiring 17 are first compared with each other, and it is judged by electrical inspection and analysis whether or not the inspection and analysis targeted circuit 14 is compatible with a final product (step 4).

Then, investigation of the cause of incompatibility if any, concurrent correction of the inspection and analysis targeted circuit 14 and inspection and analysis wiring 17, and the subsequent inspection and analysis are repeated until it is judged that the inspection and analysis targeted circuit 14 is compatible with the designed product (step 5).

Then, although the inspection and analysis targeted circuit 14 is compatible with the designed product, in the case where it is judged that a portion not formed of the circuit in the designed product should be corrected rather than the inspection and analysis targeted circuit 14, the investigation of the case of incompatibility, the concurrent correction of a circuit other than the inspection and analysis targeted circuit 14, and the subsequent inspection and analysis are repeated until such compatibility has been judged (step 6).

A final product with its excellent quality can be designed and manufactured by repeating these steps.

In the first embodiment, although the shield member 4a is brought into intimate contact with the light source side of the complete circuit forming mask 3, the shield member 4a may be located in a space between the light source and the mask 3, may be brought into intimate contact with a face opposite to the light source of the mask 3, may be disposed in a space between the mask 3 and the photo resist 13, or may be disposed in intimate contact with a surface of the photo resist 13. In addition, the shield member 4a may be a planar mask, film shaped mask or net shaped mask including a plate for shielding light or a portion for transmitting light and a portion for shielding light and switching these portions according to a pattern. Further, a light source itself may turn OFF the light, dim light or adjust an emission direction without using the shield member 4a, whereby a region to be shield is not irradiated.

In addition, the surface of the substrate 11 may be directly processed without forming a processing targeted layer 2.

Now, a second embodiment of the present invention will be described here.

In the second embodiment, a shield member provided in an incomplete circuit forming system light-shields an inspection and analysis targeted circuit, and the other configuration is similar to that according to the first embodiment.

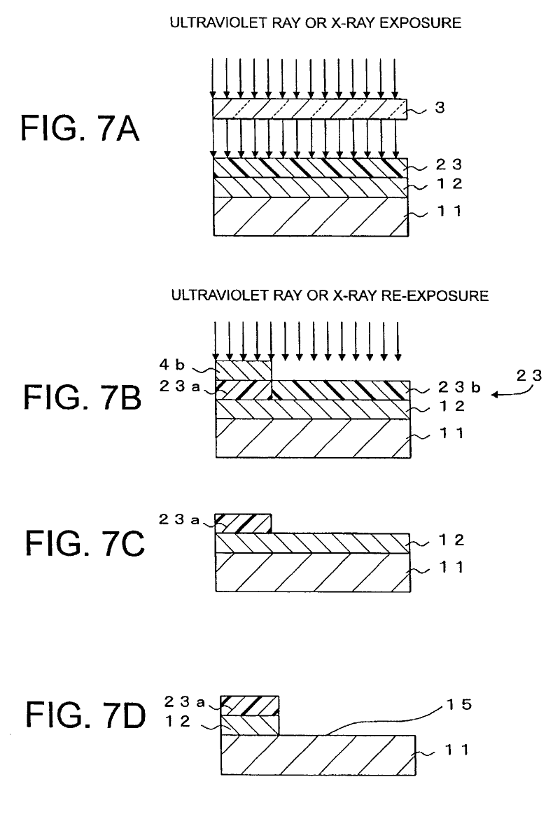

A method for manufacturing a semiconductor device by using the thus configured manufacturing apparatus according to the second embodiment will now be described here. FIG. 7A to FIG. 7D are sectional views each sequentially showing the steps of forming an inspection and analysis targeted circuit, included in the manufacturing method using the apparatus for manufacturing the semiconductor device according to the second embodiment.

At a design stage, one or more mask patterns required for manufacturing a product is first designed. A pattern of a shield member for shielding a region of a circuit targeted for inspection and analysis is then designed. The circuit targeted for inspection and analysis is a circuit included in the one or more mask patterns. Further one or more mask patterns required for manufacturing a circuit required for inspection and analysis of an inspection and analysis targeted circuit.

Next, at an actual processing stage, as shown in FIG. 7A, a processing targeted layer 12 is formed on a substrate 11. Then, a photo resist 23 is formed on the processing targeted later 12. The photo resist 23 may be characterized such that a photo-sensed portion is removed by etching and washing after exposure, for example. Then, the entire face of the photo resist 23 is exposed by an ultra-violet ray or an X-ray using the complete circuit forming mask 3. A circuit pattern formed in the complete circuit forming mask 3 is transferred to the entire region of the photo resist 23.

Next, as shown in FIG. 7B, a shield member 4b for shielding a region of an inspection and analysis targeted circuit is brought into intimate contact with the photo resist 23, and the photo resist 23 is exposed again by an ultra-violet ray or an X-ray. As a result, a circuit pattern formed in a region that is not shielded by the shield member 4b is lost. Namely, at this time, a pattern residue 23a and a pattern lost portion 23b exist in the photo resist 23.

Next, as shown in FIG. 7C, the pattern lost portion 23b in the photo resist 23 is removed by developing and washing.

Then, as shown in FIG. 7D, the pattern residue portion 23a in the photo resist 23 is defined as a mask, and the processing targeted layer 12 is etched. As a result, the processing targeted layer 12 is patterned in the shape of a circuit pattern shielded by the shield member 4b of the complete circuit forming mask 3.

Thereafter, an inspection and analysis targeted circuit is completed on a predetermined region of the substrate 11 by repeating these steps, an inspection and analysis wiring is further formed, and then, inspection and analysis similar to those according to the first embodiment are carried out.

A final product with its excellent quality can be designed and manufactured according to the second embodiment as well.

In the second embodiment, although the shield member 4b is brought into intimate contact with the photo resist 23, the shield member 4b may be disposed in a space between the light source and the photo resist 23 or may be brought into intimate contact with the light source. In addition, the shield member 4b may be a planar mask, a film shaped mask or a net shaped mask with a plate for shielding light or a portion for transmitting light and a portion for shielding light, and switching these portions according to the pattern. Further, the light source itself may turn OFF the light, dim the light or adjust an emission direction without using the shield member 4b, thereby disabling irradiation of a range to be shielded.

In addition, a surface of the substrate 11 may be directly processed without forming the processing targeted layer 2.

Now, a third embodiment of the present invention will be described here. The third embodiment relates to another manufacturing method using the apparatus similar to that according to the second embodiment.

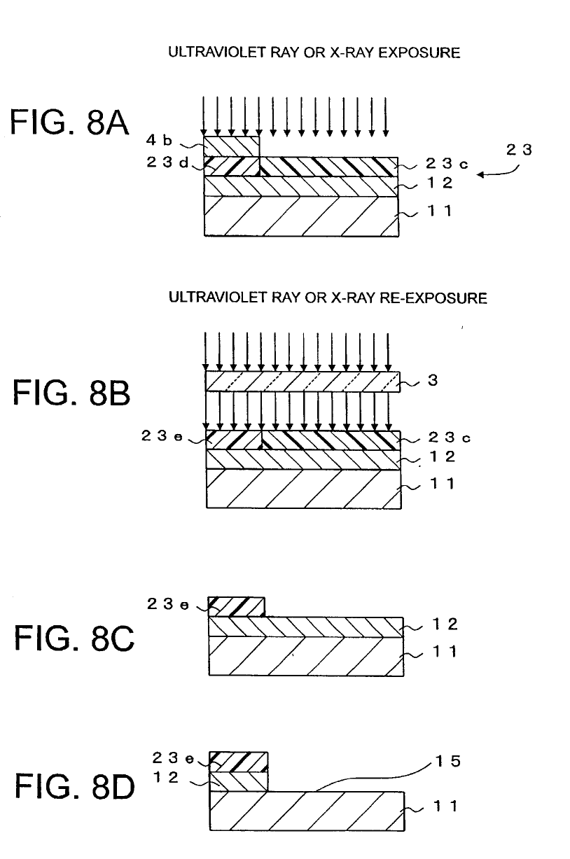

FIG. 8A to FIG. 8D are sectional views each sequentially showing the steps of forming an inspection and analysis targeted circuit, included in a method for manufacturing a semiconductor device according to the third embodiment.

At a design stage, one or more mask patterns required for manufacturing a product are first designed. Some of the circuits included in these patterns are then designed as a pattern of a shield member for shielding a region of an inspection and analysis targeted circuit. Further, there are designed one or more mask patterns required for manufacturing a circuit required for inspection and analysis of an inspection and analysis targeted circuit.

Next, at an actual processing stage, as shown in FIG. 8A, a processing targeted layer 12 is formed on a substrate 11. Then, a photo resist 23 is formed on the processing targeted layer 12. The photo resist 23 may be characterized such that a photo-sensed portion is removed by etching and washing after exposure, for example, as in the second embodiment. Then, a shield member 4b for shielding a region of an inspection and analysis targeted circuit is brought into intimate contact with the photo resist 23, and the photo resist 23 is exposed by an ultra-violet ray or an X-ray. As a result, a photosensitive portion 23c is formed in a region free of being shielded by the shield member 4b, and a non-photosensitive portion 23d is formed in a region that has been shielded.

Next, as shown in FIG. 8B, the entire surface of the photo resist 23 is exposed by an ultra-violet ray or X-ray using the complete circuit forming mask 3. As a result, at the non-photosensitive portion 23d, a circuit pattern formed at the complete circuit forming mask 3 is transferred, and a pattern transfer portion 23e is formed. At the photosensitive portion 23c, the entire face has already been photo-sensed, and thus, a circuit pattern is not transferred.

Next, as shown in FIG. 8C, the photosensitive portion 23c in the photo resist 23 is removed by developing and washing.

Then, as shown in FIG. 8D, a pattern transfer portion 23e of the photo resist 23 is defined as a mask, and a processing targeted layer 12 is etched. As a result, the processing targeted layer 12 is patterned in the shape of a circuit pattern shielded by the shield member 4b of the complete circuit forming mask 3.

Then, an inspection and analysis targeted circuit is completed on a predetermined region of the substrate 11 by repeating these steps, and inspection and analysis similar to those according to the first embodiment are carried out.

In the third embodiment, although the shield member 4b is brought into intimate contact with the photo resist 23, the shield member 4b may be disposed in a space between the light source and the photo resist 23 or may be brought into contact with the light source, as in the second embodiment. In addition, the shield member 4b may be a planar mask, a film shaped mask or a net shaped mask with a plate for shielding light or a portion for transmitting light and a portion for shielding light, and switching these portions according to the pattern. Further, the light source itself may turn OFF the light, dim the light or adjust an irradiation direction without using the shield member 4b, thereby disabling irradiation of a range to be shielded.

In addition, a surface of the substrate 11 may be processed without forming the processing targeted layer 2.

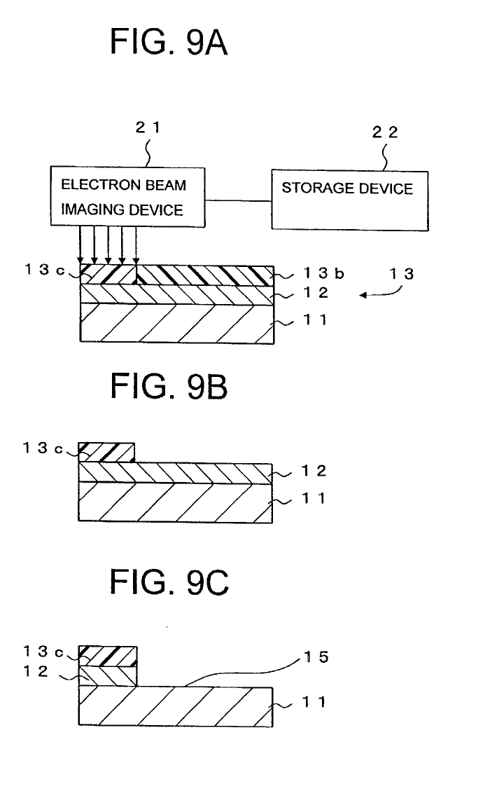

Now, a fourth embodiment of the present invention will be described here. According to the fourth embodiment, a pattern is directly imaged at a photo resist by using electron beams or the like. FIG. 9A to FIG. 9C are sectional views each sequentially showing the steps of forming an inspection and analysis targeted circuit, included in a method for manufacturing a semiconductor device according to the fourth embodiment.

At a design stage, one or more mask patterns required for manufacturing a product are first designed. Some of the circuits included in these patterns are then designed as a pattern of an inspection and analysis targeted circuit. Further, there are designed one or more mask patterns required for manufacturing a circuit required for inspection and analysis of an inspection and analysis targeted circuit. Then, a structure of the inspection and analysis targeted circuit is stored in a storage device 22 which an electron beam imaging device 21 can access.

Next, at an actual processing stage, as shown in FIG. 9A, a processing targeted layer 12 is formed on a substrate 11. Then, a photo resist 13 is formed on the processing targeted layer 12. This photo resist 13 may be characterized such that a portion free of being photo-sensed, for example, is removed by etching and washing after exposure similar to that in the first embodiment. At a portion corresponding to a region of an inspection and analysis targeted circuit of the photo resist 13, a circuit pattern based on a structure stored in the storage device 22 is directly imaged by an electron beam imaging device 21. As the electron beam imaging device 21, there can be used a stepping type projection exposure device or a scanning type exposure device, for example. As a result, a pattern forming portion 13c and a non-photosensitive portion 13b are formed at the photo resist.

Next, as shown in FIG. 9B, a non-photosensitive portion 13b in the photo resist 13 is removed by developing and washing.

Then, as shown in FIG. 9C, a pattern forming portion 13c in the photo resist 13 is defined as a mask, and a processing targeted layer 12 is etched. As a result, the processing targeted layer 12 is patterned in the shape of a circuit pattern based on a structure stored in the storage device 22.

Thereafter, an inspection and analysis targeted circuit 14 is completed by repeating these steps, and inspection and analysis similar to those according to the first embodiment are carried out.

A structure of an inspection and analysis targeted circuit stored in the storage device 22 may be a planar two-dimensional structure or may be a stereoscopic three-dimensional structure. These structures are defined as a set of the positional coordinate values. Then, a range of the inspection and analysis targeted circuit is defined by its outer contour.

In addition, in the fourth embodiment, a two-dimensional coordinate or a three-dimensional coordinate including a vertical direction is stored in the storage device 22, and the thus stored coordinate is used for specifying the coordinate during direct imaging. However a plate member, film or the like for shielding, changing or dispersing irradiation routes of electron beams may be provided between the electron beam imaging device 21 and the photo resist 13, whereby electron beams may be shielded or attenuated before electron beams have arrived at a photo resist in a region other than the inspection and analysis targeted circuit 14.

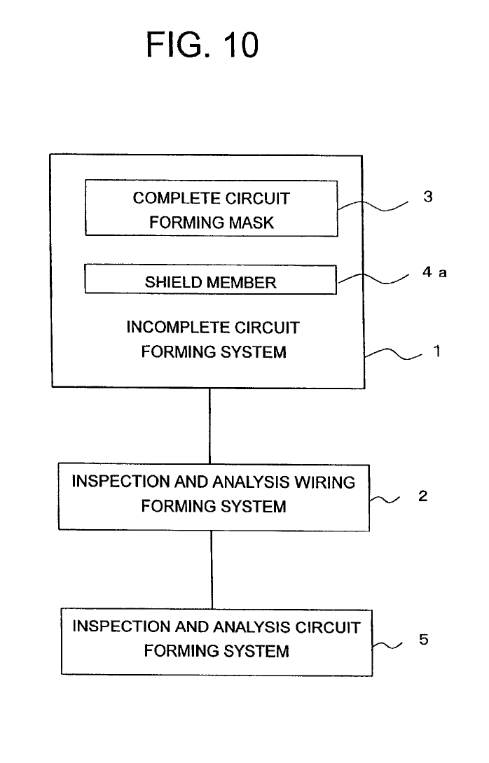

Now, a fifth embodiment of the present invention will be described here. FIG. 10 is a block diagram depicting an apparatus for manufacturing a semiconductor device according to the fifth embodiment.

In the fifth embodiment, there is provided an inspection and analysis circuit forming system 5 for forming an inspection and analysis circuit as well as an incomplete circuit forming system 1 and an inspection and analysis wiring forming system 2. The inspection and analysis circuit is a circuit for carrying out more detailed inspection and analysis of an inspection and analysis targeted circuit.

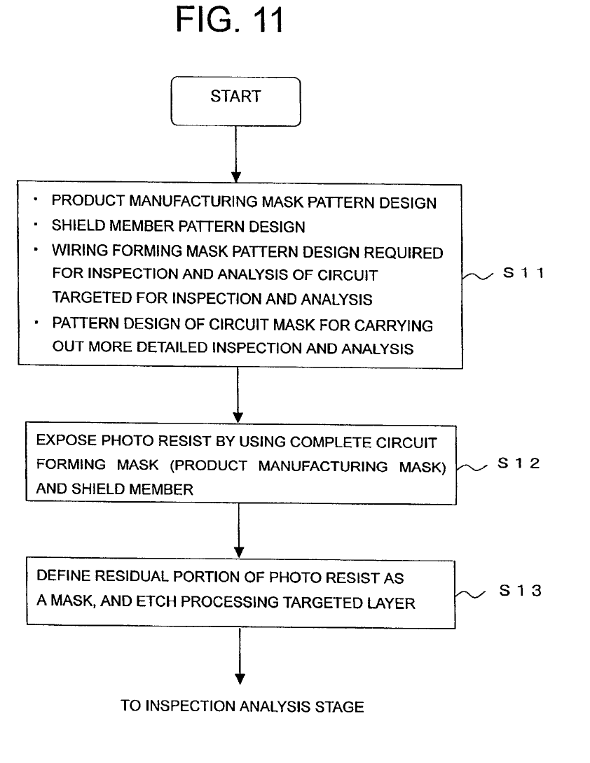

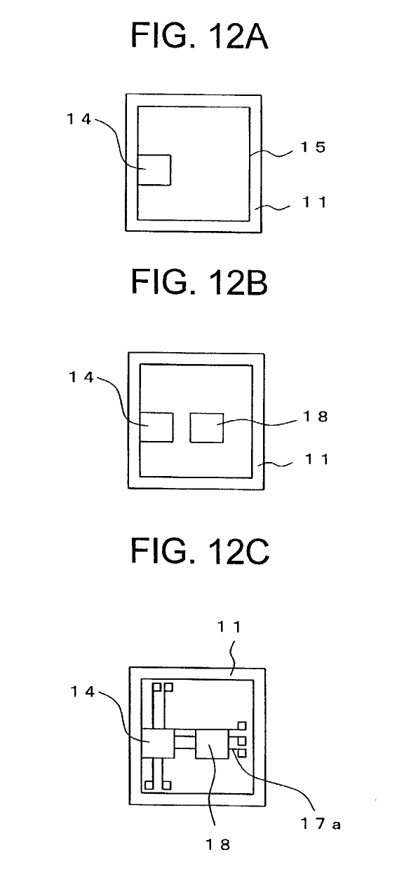

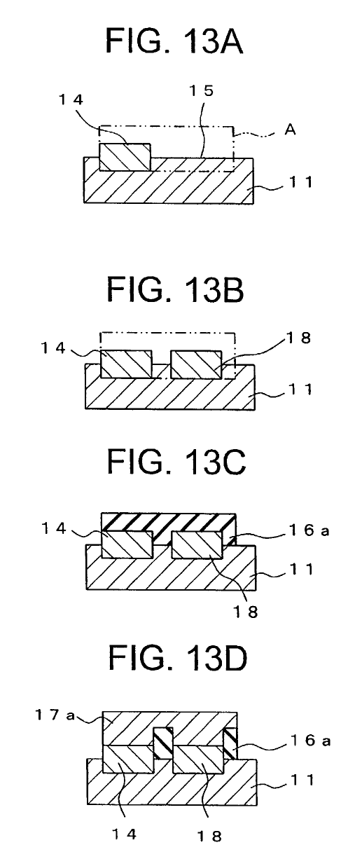

Now, a method for manufacturing a semiconductor device by using the thus configured manufacturing apparatus according to the fifth embodiment will be described here. FIG. 11 is a flow chart showing a method for manufacturing a semiconductor device. FIG. 12A to FIG. 12C are plan views each sequentially showing the steps of forming an inspection and analysis wiring and an inspection and analysis circuit, included in the manufacturing method using the apparatus for manufacturing the semiconductor device according to the fifth embodiment of the present invention. FIG. 13A to FIG. 13D are sectional views each sequentially showing the same steps.

In the manufacturing method using the manufacturing apparatus according to the fifth embodiment, at its design stage, one or more mask patterns required for manufacturing a product are designed. Some of the circuits included in these patterns are then designed as a pattern of a shield member for preventing formation of a region of a circuit that is not required for inspection and analysis of an inspection and analysis targeted circuit. Further, there are designed one or more mask patterns required for manufacturing a wiring required for inspection and analysis of the inspection and analysis targeted circuit and a circuit for carrying out more detailed inspection and analysis (step S11).

Next, at an actual processing stage, a photo resist is exposed with using a complete circuit forming mask and a shield member (step S12), and the photo resist is patterned by development and the like, as the first embodiment.

Then, a remaining photo resist is defined as a mask, and a processing targeted layer is etched (step S13). By repeating these steps, as shown in FIG. 12A and FIG. 13A, an inspection and analysis targeted circuit 14 is completed on a predetermined region of the substrate 11. At this time, on the substrate 11 light-shielded by the shield member, there exists a region 15 in which a circuit pattern does not exist.

Next, as shown in FIG. 12B and FIG. 13B, an inspection and analysis circuit 18 is formed in the region 15.

Then, as shown in FIG. 13C, an interlayer insulation layer 16a is formed on the entire face including the region 15. As a result, the region 15 is completely covered with an interlayer insulation film 16a.

Further, while the other insulation film and a wiring layer (not shown) or the like are formed in a proper number of layers on the interlayer insulation film 16a, as shown in FIG. 12C and FIG. 13D, an inspection and analysis targeted circuit 14 is connected to an inspection and analysis circuit 18, thereby forming an inspection and analysis wiring 17a used for inspection and analysis of an operation of the inspection and analysis targeted circuit 14.

In parallel to such manufacturing steps, a circuit in a product designed by using a complete circuit forming mask 3 without using a shield member or the like is also manufactured at the same time.

Some of the circuits included in the designed product should be formed in a region in which such forming is prevented by the shield member, and are indispensable for an operation of the inspection and analysis targeted circuit 14. Therefore, in such a case, such indispensable circuits or wirings are included in the inspection and analysis wiring 17a, and an interlayer insulation film 16a is passed, whereby connection to a circuit substantially required for inspection and analysis may be made.

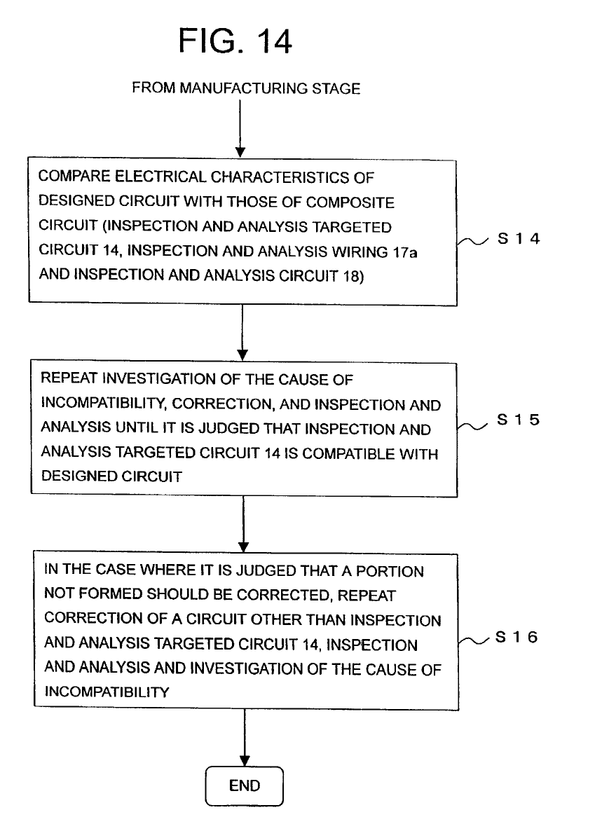

Then, inspection and analysis similar to those according to the first embodiment are carried out. FIG. 14 is a flow chart showing a method for inspecting a semiconductor device manufactured according to the fifth embodiment.

At an inspection and analysis stage, there are compared with each other electrical characteristics of a designed circuit formed on the same substrate 11 and a composite circuit of an inspection and analysis targeted circuit 14, an inspection and analysis wiring 17a and an inspection and analysis circuit 18, and it is judged by electrical inspection and analysis whether or not the inspection and analysis targeted circuit 14 are compatible with a final product (step 14).

Then, investigation of the cause of incompatibility if any, the concurrent correction of the inspection and analysis targeted circuit 14, inspection and analysis wiring 17a and inspection and analysis circuit 18, and the subsequent inspection and analysis are repeated until it is judged that the inspection and analysis targeted circuit 14 is compatible with the designed product (step S15).

Then, although the inspection and analysis targeted circuit 14 is compatible with the designed product, in the case where it is judged that a portion not formed of the circuit in the designed product should be corrected, the investigation of the case of incompatibility, the concurrent correction of a circuit other than the inspection and analysis targeted circuit 14, and the subsequent inspection and analysis are repeated until such compatibility has been judged (step 16).

A final product with its excellent quality can be designed and manufactured by repeating these steps. At this time, more detailed inspection and analysis than those according to the first embodiment can be carried out by using an inspection and analysis circuit 18.

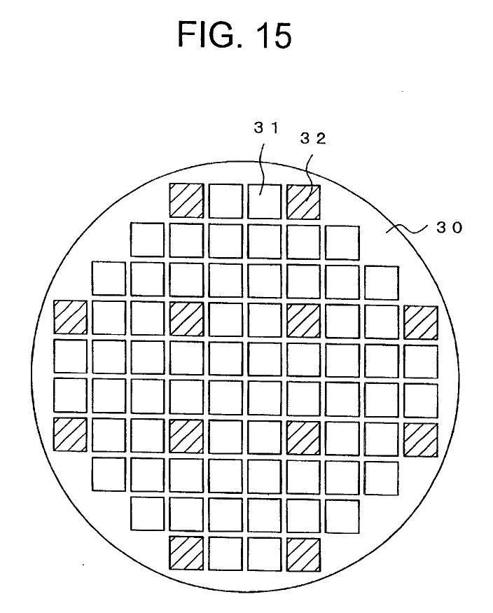

Now, examples of layout in a semiconductor wafer when the first to fifth embodiments are used will be described here. FIG. 15 is a plan view showing an example of a layout in a wafer when any one of the first to fifth embodiments is used.

When the manufacturing apparatus according to these embodiment is used, as shown in FIG. 15, a designed product semiconductor device 31 (hatched) and an inspection semiconductor device 32 (not hatched) can be disposed on the same wafer 30 to be mixed with arbitrary combination. Here, the inspection semiconductor device 32 includes the inspection and analysis targeted circuit 14 and the inspection and analysis wiring 17 in the first to fourth embodiments. This semiconductor device 32 includes the inspection and analysis targeted circuit 14, inspection and analysis wiring 17a and inspection and analysis circuit 18 in the fifth embodiment. On the other hand, the product semiconductor device 31 is a designed circuit manufactured without using a shield member 4a or the like in parallel to the inspection semiconductor device 32. In addition, of the wafer 30, a portion other than the designed product semiconductor device 31 and inspection semiconductor device 32 is cut out or discarded when separating circuit LSIs such as these LSIs.

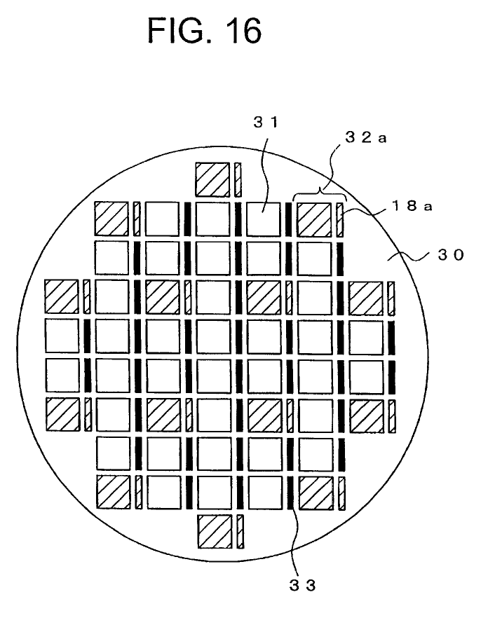

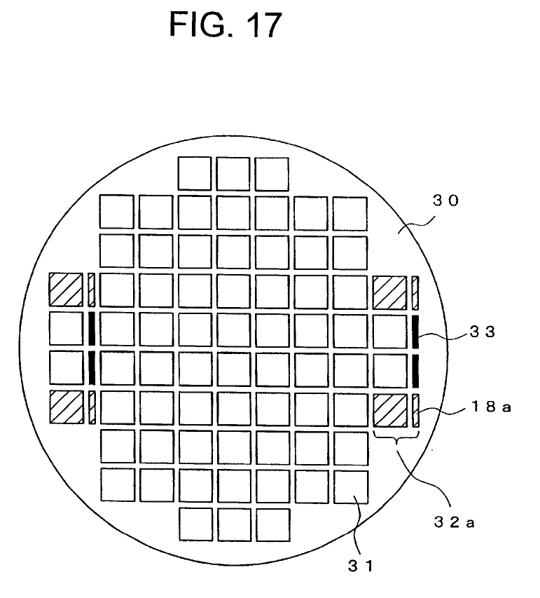

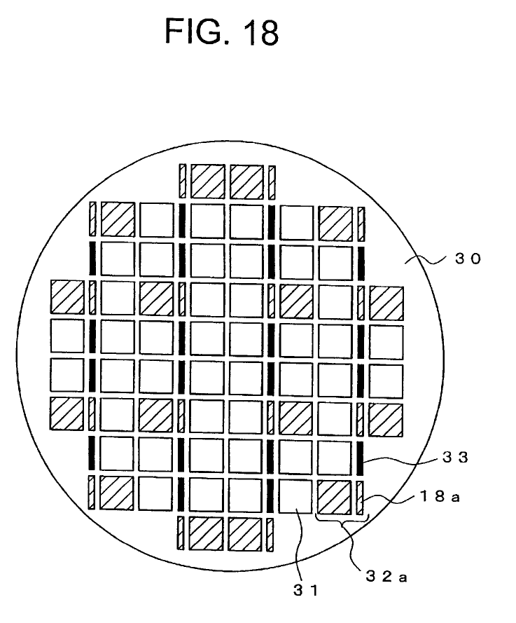

Now, a sixth embodiment of the present invention will be described here. As shown in FIG. 15, in the first to fifth embodiments, the inspection semiconductor device 32 is disposed at a portion at which the original product semiconductor device 31 is disposed. However, in a sixth embodiment, there is provided an inspection and analysis composite circuit at a position shifted from a position at which the product circuit is disposed as well. FIG. 16 is a plan view showing a first example of a layout in the sixth embodiment. FIG. 17 is a plan view showing a second example of a layout in the sixth embodiment. FIG. 18 is a plan view showing a third example of a layout in the sixth embodiment.

In the sixth embodiment, for example, as shown in FIG. 16, in the case where only a designed product semiconductor device 31 is formed on a wafer 30, a portion of the inspection semiconductor device 32a, for example, an inspection and analysis circuit 18a is formed at a portion to be cut out or discarded. In this case, a portion 33 of the inspection semiconductor device 32a (filled) is formed at a portion to be originally cut out or discarded, the portion being positioned transversely of the product semiconductor device 31 as well. This portion 33 is then cut out or discarded in the step of separating an LSI chip.

In a first example shown in FIG. 16, 50 LSIs, for example, are assigned on one wafer 30, 14 of which are defined as an inspection semiconductor device 32a. However, as in a second example shown in FIG. 17, 70 LSIS, for example, are assigned on one wafer 30, 4 of which may be defined as an inspection semiconductor device 32a. Further, as in a third example shown in FIG. 18, 60 LSIS, for example, are assigned on one wafer 30, 16 of which may be defined as an inspection semiconductor device 32a. In comparing these examples, according to the first example, although the number of product semiconductor devices 31 is reduced, a restriction on mixture ratio or disposition method can be reduced. In addition, according to the second example, the restriction on mixture ratio or disposition method is increased, but the number of product semiconductor devices 31 can be increased. Further, according to the third example, the intermediate characteristics of the first and second examples can be provided. The present invention is not limited to these layout examples.

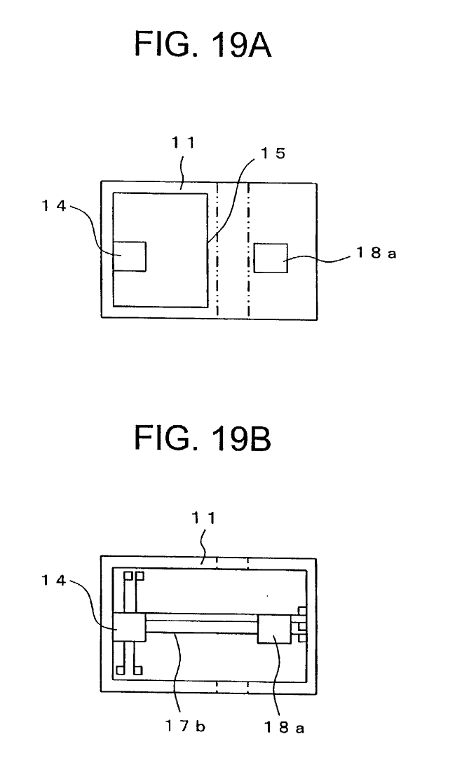

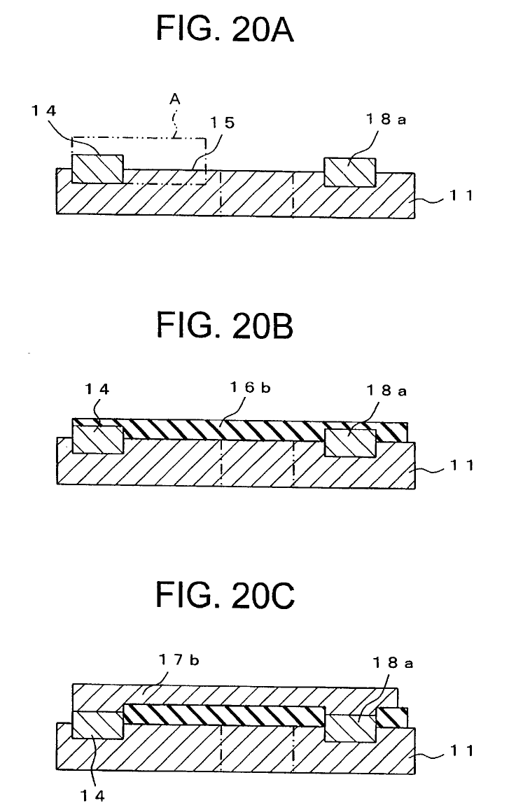

Now, a method for manufacturing a semiconductor device according to a sixth embodiment employing the above-described layouts will be described here. FIG. 19A and FIG. 19B are plan views each sequentially showing the steps of forming an inspection and analysis wiring and an inspection and analysis circuit, included in the manufacturing method using the apparatus for manufacturing the semiconductor device according to the sixth embodiment. FIG. 20A to FIG. 20C are sectional views sequentially showing the same steps.

In the sixth embodiment, at its design stage, there are designed one or more mask patterns required for manufacturing a product and required for manufacturing an inspection and analysis circuit. Some of the circuits included in these patterns are then designed as a pattern of a shield member for preventing formation of a region of a circuit that is not required for inspection and analysis of an inspection and analysis targeted circuit. The former pattern is provided in a region that differs from each of a pattern required for manufacturing a product and a pattern required for manufacturing an inspection and analysis circuit, as shown in FIG. 16 to FIG. 18. Further, there is designed a wiring mask pattern required for inspection and analysis of an inspection analysis targeted circuit.

Next, at an actual processing stage, as in the first embodiment or the like, a photo resist is exposed in one-shot by using a mask and a shield member, and this photo resist is patterned by developing and the like.

Then, the remaining photo resist is defined as a mask, and a processing targeted layer is etched. By repeating these steps, as shown in FIG. 19A and FIG. 20A, an inspection and analysis targeted circuit 14 and an inspection and analysis circuit 18a are completed on a predetermined region of the substrate 11. Although the inspection and analysis targeted circuit 14 may be formed in a region in which the product semiconductor device is originally formed, the inspection and analysis circuit 18a may be formed in a region sandwiched between two product circuits. Conventionally, this portion corresponds to a portion cut out or discarded in the step of separating an LSI chip from a wafer.

Then, as shown in FIG. 20B, an interlayer insulation film layer 16b is formed on the entire face.

Further, while the other insulation film and a wiring layer (not shown) or the like are formed in a proper number of layers on the interlayer insulation film 16b, as shown in FIG. 19B and FIG. 20C, the inspection and analysis targeted circuit 14 is connected to the inspection and analysis circuit 18a, thereby forming an inspection and analysis wiring 17b used for inspection and analysis of an operation of the inspection and analysis targeted circuit 14.

In parallel to such a manufacturing steps, a circuit in the designed circuit without using a shield member or the like is also manufactured at the same time.

Some of the circuits included in the designed product should be formed in a region in which such forming is prevented by a shield member, and are indispensable for an operation of the inspection and analysis targeted circuit 14. Therefore, in such a case, such indispensable circuits or wirings are included in the inspection and analysis wiring 17b, and an interlayer insulation film 16a is passed, whereby connection to a circuit substantially required for inspection and analysis may be made.

In this way, according to the sixth embodiment, the product semiconductor device 31 can be manufactured in parallel to the inspection semiconductor device 32a. Thus, the number of steps can be reduced as compared with those according to the fifth embodiment. In addition, according to the sixth embodiment, a portion including the product semiconductor device 31 can be separated from a portion including an inspection and analysis circuit 18a. Therefore, the semiconductor device for the purpose of manufacturing can be disposed to be mixed with a device for the purpose of inspection and analysis on the same wafer.

What is claimed is:

1. An apparatus for manufacturing a semiconductor device with an inspection semiconductor device which is used to inspect the product semiconductor device, said apparatus comprising:
a pattern forming unit which forms an incomplete circuit pattern, said incomplete circuit pattern including a circuit targeted for inspection in said product semiconductor device and the other circuit of said product semiconductor device which is not targeted for inspection and in which at least an arbitrary portion of the other circuit is missing; and
a device forming unit which couples arbitrary circuit pattern with said missing portion to form said inspection semiconductor device.

2. The apparatus for manufacturing a semiconductor device according to claim 1, wherein said product semiconductor device and said inspection semiconductor device are formed in a same semiconductor wafer.

3. A method for manufacturing a semiconductor device with an inspection semiconductor device which is used to inspect the product semiconductor device, said method comprising the steps of:
forming an incomplete circuit pattern, said incomplete circuit pattern including a circuit targeted for inspection in said product semiconductor device and the other circuit of said product semiconductor device which is not targeted for inspection and in which at least an arbitrary portion of the other circuit is missing; and
coupling arbitrary circuit pattern with said missing portion to form said inspection semiconductor device.

4. The method for manufacturing a semiconductor device according to claim 3, wherein in forming said incomplete circuit pattern, a product mask pattern for said product semiconductor device is transferred with a region which corresponds to said arbitrary portion of said product mask pattern being shielded.

5. The method for manufacturing a semiconductor device according to claim 3, wherein in forming said incomplete circuit pattern, a product mask pattern for said product semiconductor device is transferred, and a region which corresponds to said arbitrary portion is removed.

6. The method for manufacturing a semiconductor device according to claim 4, wherein in transferring said product mask pattern, one kind of method selected from a group consisting of exposure, printing and imaging is adopted.

7. The method for manufacturing a semiconductor device according to claim 5, wherein in transferring said product mask pattern, one kind of method selected from a group consisting of exposure, printing and imaging is adopted.

8. The method for manufacturing a semiconductor device according to claim 3, wherein in coupling said arbitrary circuit pattern, said arbitrary circuit pattern is transferred on a semiconductor substrate same as said incomplete circuit pattern, and said incomplete circuit pattern is coupled with said arbitrary circuit pattern via a wiring having a switch enabling divergence and disconnection.

9. The method for manufacturing a semiconductor device according to claim 3, wherein in coupling said arbitrary circuit pattern, said arbitrary circuit pattern is transferred on a semiconductor substrate that differs from said incomplete circuit pattern, and said incomplete circuit pattern is coupled with said arbitrary circuit pattern via a wiring having a switch enabling divergence and disconnection.

10. An inspection apparatus for an inspection semiconductor device manufactured by said manufacturing apparatus according to claim 1, comprising a comparator which compares electrical characteristics of said product semiconductor device with those of a circuit in a region corresponding to said incomplete circuit pattern.

11. An inspection apparatus for an inspection semiconductor device manufactured by said manufacturing apparatus according to claim 2, comprising a comparator which compares electrical characteristics of said product semiconductor device with those of a circuit in a region corresponding to said incomplete circuit pattern.

12. An inspection method for an inspection semiconductor device manufactured by said manufacturing apparatus according to claim 1, comprising the step of comparing electrical characteristics of said product semiconductor device with those of a circuit in a region corresponding to said incomplete circuit pattern.

13. An inspection method for an inspection semiconductor device manufactured by said manufacturing apparatus according to claim 2, comprising the step of comparing electrical characteristics of said product semiconductor device with those of a circuit in a region corresponding to said incomplete circuit pattern.
